(19) United States
(12) Patent Application Publication
(10) Pub. No.: US 2026/0079547 A1
(43) Pub. Date: Mar. 19, 2026

(54) Configurable Power Management Integrated Circuit with Voltage Regulation Units and Shared Reference Voltage

(71) Applicant: PowerLattice Technologies Inc., Camas, WA (US)

(72) Inventors: Gang Ren, Camas, WA (US); Peng Zou, Camas, WA (US); Sujith S. Dermal, Chandler, AZ (US)

(21) Appl. No.: 19/330,739

(22) Filed: Sep. 16, 2025

Related U.S. Application Data
(60) Provisional application No. 63/696,457, filed on Sep. 19, 2024.

(51) Int. Cl. G06F 1/18; G06F 1/3234; H01L 23/50; H01L 23/538; H01L 25/18; H10B 80/00; H10D 80/30

(52) U.S. Cl. CPC G06F 1/189; G06F 1/3234; H10W 70/611; H10W 70/65; H10W 72/00; H10W 90/00; H10B 80/00; H10D 80/30

(57) ABSTRACT

This application is directed to providing rail voltages for an electronic system. In some examples, an electronic system includes a first chiplet and a second chiplet. Each of the first chiplet and second chiplet include a plurality of voltage regulation units configured to provide a voltage regulator set. The first chiplet also includes a reference circuit electrically coupled to the voltage regulator set and configured to generate a reference voltage. Further, the first voltage regulator set of the first chiplet is configured to generate a rail voltage based on the reference voltage from the reference circuit. In addition, the voltage regulator set of the first chiplet is configured to provide the rail voltage to a power rail, and provide the reference voltage to the regulator set of the second chiplet to generate the same or different rail voltage.

### RELATED APPLICATION

This application claims priority to U.S. Provisional Patent Application No. 63/696,457, entitled “A Powering Large Cpu/Gpu Voltage Domain With A Group Of Voltage Regulation Units From A Scalable Array Of Voltage Regulation Units Located Across Multiple Chips,” filed Sep. 19, 2024, and is incorporated herein by reference to its entirety.

### TECHNICAL FIELD

This application relates generally to power management of an electronic system, including, but not limited to, methods, systems, devices, and integrated circuits for providing rail voltages to drive power rails of the electronic system.

### BACKGROUND

A System on Chip (SoC) consolidates multiple components of a computer, such as a processor, memory, input/output interfaces, and various peripherals, on a substrate. SoCs are widely used in modern electronics, including smartphones, tablets, and embedded systems, where space, power efficiency, and performance are critical. To manage complex power requirements of these components, a Power Management Integrated Circuit (PMIC) is often employed. A PMIC can include Voltage Regulation Units (VRUs) that are responsible for regulating, distributing, and controlling the power delivered to an SoC's various subsystems. For example, a PMIC can manage multiple voltage levels, enabling features like dynamic voltage scaling to conserve energy and ensure the SoC operates within its power and thermal limits. Together, an SoC and PMIC form a system capable of handling diverse tasks with reduced power consumption, making them essential in today's compact, high-performance devices.

Many applications today, such as Artificial Intelligence (AI), and Machine Learning based applications, can require high performance computing workloads. For instance, the power supply domains within such systems can experience several thousands of Amperes load current. In an effort to provide such power, conventional systems may rely on power supplies with enough VRUs to deliver the needed power. In some instances, the VRUs are spread across multiple Voltage Regulation (VR) chips (i.e., VR chiplets). The fabrication variation of these VR chips naturally leads to varying reference voltage levels at each VR chip, even when the VR chips are similarly configured. This can lead to consistency issues (e.g., when different power rails fail to deliver uniform voltage levels or fail to sequence properly) and/or stability issues (e.g., where voltage fluctuations, oscillations, or noise occur within a single rail) when providing power on various power rails. These issues can cause intermittent failures, timing errors, or degraded performance in an SoC.

### SUMMARY

In accordance with at least some implementations disclosed herein is the realization that an SoC operates more efficiently when consistent and reliable power delivery is provided on its power rails. For instance, an SoC operates more efficiently when each power rail delivers its rail voltage consistently. In some implementations, an SoC may receive power from different power rails that provide the same rail voltage, and the SoC may operate more efficiently when the power rails are consistent with one another. Various implementations of this application are directed to methods, systems, devices, and integrated circuits for generating and distributing a common shared reference signal to one or more VR chips. The common shared reference signal can be provided to a portion, or all, of the Voltage Regulation Units of each VR chip. As a result, VR units within multiple VR chips can operate based on the same voltage reference signal. Moreover, in some implementations, a VR chip can be configured in one of a variety of modes. For instance, one VR chip can be configured as a reference signal master, and other VR chips can be configured as reference signal slaves. The VR chip configured as a reference signal master can drive the reference signal as an output via one or more reference signal pins, and the VR chips configured as reference signal slaves can receive the reference signal via one or more reference signal pins.

Among other advantages, the embodiments described herein can reduce or eliminate consistency and/or stability issues across various VR chips, such as when the various VR chips are providing power on a common power rail. Moreover, by sharing a common reference signal, cross-chip (i.e., cross-chiplet) power rails can intuitively achieve synchronization and matched voltage, leading to more effective load balancing across a system.

In some implementations, an electronic system includes a plurality of chiplets including at least a first chiplet and a second chiplet. Each of the plurality of chiplets include a plurality of voltage regulation units configured to provide at least a first voltage regulator set. The first voltage regulator set of the first chiplet is configured to: generate a first rail voltage based on a reference voltage; provide the first rail voltage to a first power rail; and provide the reference voltage to the first voltage regulator set of the second chiplet. In addition, the first voltage regulator set of the second chiplet is configured to: generate a second rail voltage based on the reference voltage; and provide the second rail voltage to a second power rail.

In other implementations, an electronic system includes a plurality of power rails configured to provide one or more rail voltages, a first chiplet, and a second chiplet. The first chiplet that includes a plurality of voltage regulation units coupled to the plurality of power rails and a reference circuit coupled to the plurality of voltage regulation units. The plurality of voltage regulation units are configured to provide a voltage regulator set, and the voltage regulator set is configured to output a rail voltage to a power rail of the plurality of power rails. In addition, the reference circuit is configured to provide a reference voltage to the plurality of voltage regulation units, wherein the voltage regulator set is configured to generate the rail voltage based on the reference voltage. In addition, the reference circuit is configured to provide the reference voltage to the second chiplet. The second chiplet is configured to output at least one of the one or more rail voltages to at least one of the plurality of power rails based on the reference voltage.

In yet other implementations, an electronic system includes a power rail configured to provide a rail voltage and a first chiplet. The first chiplet includes a plurality of voltage regulation units configured to provide a voltage regulator set, and the voltage regulator set is configured to output the rail voltage to the power rail. In addition, the first chiplet is configured to receive a reference voltage from a second chiplet, and provide the reference voltage to the plurality of voltage regulation units of the voltage regulator set. The voltage regulator set is configured to generate the rail voltage based on the reference voltage.

In some other implementations, a method is implemented to provide a rail voltage for an electronic system. The method includes grouping voltage regulation units within a first chiplet to provide a voltage regulator set. The method also includes coupling a reference circuit to the voltage regulator set, wherein the reference circuit is configured to generate a reference voltage and provide the reference voltage to the voltage regulator set and to a reference signal pin.

In some other implementations, a method is implemented to provide a rail voltage for an electronic system. The method includes generating a reference voltage by a reference circuit, and providing the reference voltage to a voltage regulator set comprised of a plurality of voltage regulation units. Further, the method includes generating a rail voltage by the voltage regulator set based on the reference voltage, and providing the rail voltage to a power rail. The method also includes providing the reference voltage to a reference signal pin electrically coupled to a chiplet.

In yet other implementations, a method is implemented to provide a rail voltage for an electronic system. The method includes receiving, from a chiplet, a reference voltage, and providing the reference voltage to a voltage regulator set comprised of a plurality of voltage regulation units. The method also includes generating, by the voltage regulator set, a rail voltage based on the reference voltage, and providing the rail voltage to a power rail.

These illustrative implementations and implementations are mentioned not to limit or define the disclosure, but to provide examples to aid understanding thereof. Additional implementations are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a block diagram of an example electronic system, in accordance with some implementations.

FIGS. 2A and 2B are a top perspective view and a bottom perspective view of an example electronic system, in accordance with some implementations, respectively.

FIGS. 3A and 3B are a top perspective view and a bottom perspective view of another example electronic system, in accordance with some implementations, respectively.

FIGS. 4A and 4B are block diagrams of an example PMIC module, in accordance with some implementations.

FIG. 5 is a schematic diagram of an example voltage regulation unit, in accordance with some implementations.

FIG. 6 is a diagram illustrating example voltage regulation units for providing a rail voltage, in accordance with some implementations.

FIG. 7A is a perspective view of an example PMIC chip including a plurality of inductors coupled in a plurality of voltage regulation units, in accordance with some implementations.

FIGS. 7B and 7C are two cross sectional views of a portion of the PMIC chip shown in FIG. 7A including two inductors of two voltage regulation units, in accordance with some implementations.

FIG. 8 is a block diagram of example voltage regulation chiplets configured to share reference voltages, in accordance with some implementations.

FIG. 9 illustrates an example of a configuration circuit for generating a reference voltage, in accordance with some implementations;

FIGS. 10A and 10B illustrate block diagrams of example chiplets in various reference voltage configurations, in accordance with some implementations.

Like reference numerals refer to corresponding parts throughout the several views of the drawings.

### DETAILED DESCRIPTION

Reference will now be made in detail to specific implementations, examples of which are illustrated in the accompanying drawings. In the following detailed description, numerous non-limiting specific details are set forth in order to assist in understanding the subject matter presented herein. As such, however, it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic devices with storage capabilities.

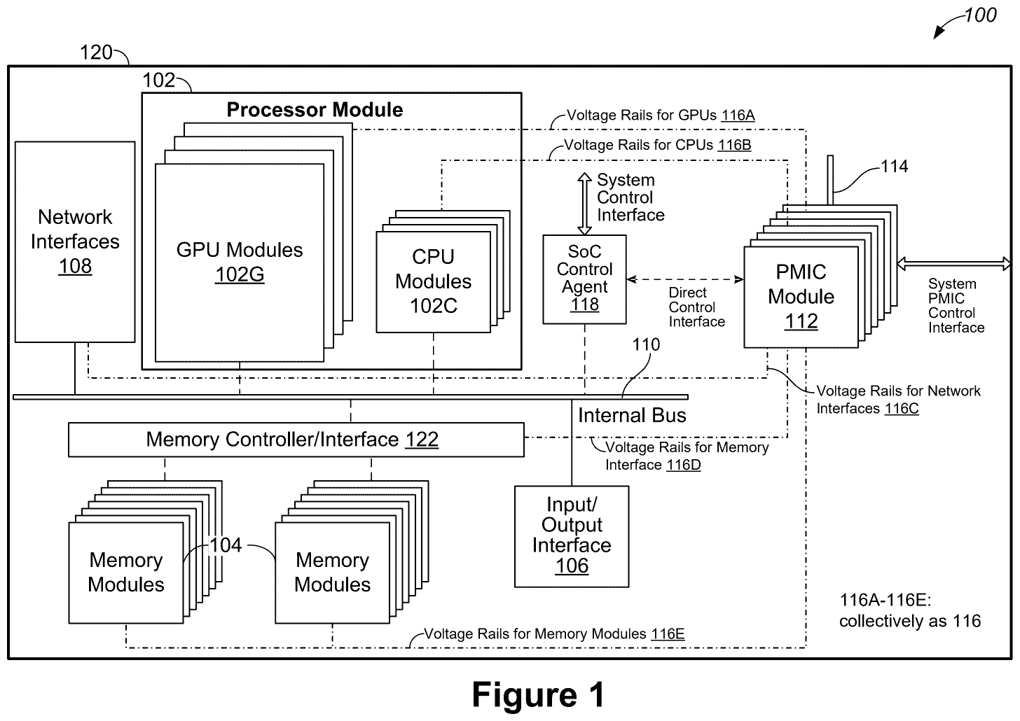

Referring now to the figures, FIG. 1 is a block diagram of an example electronic system 100, in accordance with some implementations. The electronic system 100 includes at least one processor module 102 (e.g., central processing unit (CPU), graphical processing unit (GPU), etc.), memory modules 104, an input/output (I/O) interface 106, one or more communication interfaces such as network interfaces 108, and one or more communication buses 110 for interconnecting these components. In some implementations, the I/O interface 106 allows the processor module 102 to communicate with an I/O device (e.g., a keyboard, a mouse or a trackpad). The I/O interface 106 may comply with a data communication bus standard including, but not limited to, universal serial bus (USB) and peripheral component interconnect express (PCIe). In some implementations, the communication bus(es) 110 include circuitry (sometimes called a chipset) that interconnects and controls communications among various system components included in electronic system 100. In some implementations, the electronic system 100 further includes other specialized hardware (e.g., wireless radios, graphics card, sound card, sensors).

In some implementations, the electronic system 100 further includes a PMIC module 112 configured to receive an input supply voltage 114. The PMIC module 112 is configured to modulate the received input supply voltage 114 to desired DC voltage levels (e.g., 1 V, 0.8 V, 0.7 V, or 0.5 V) as required by various components or circuits (e.g., the processor module 102) within the electronic system 100. For example, the PMIC module 112 is configured to generate the DC voltage levels at a plurality of power rails 116 for providing power to other components (e.g. components 102-110) in the electronic system 100. Examples of the plurality of power rails 116 include, but are not limited to: one or more GPU power rails 116A, one or more CPU power rails 116B, one or more networking power rails 116C, one or more memory interface power rails 116D, and one or more memory module power rails 116E. In some implementations, the PMIC module 112 further includes a layer within a printed circuit board (PCB) or an integrated circuit (IC), and the layer is applied as an input power plane for distributing the input supply voltage 114.

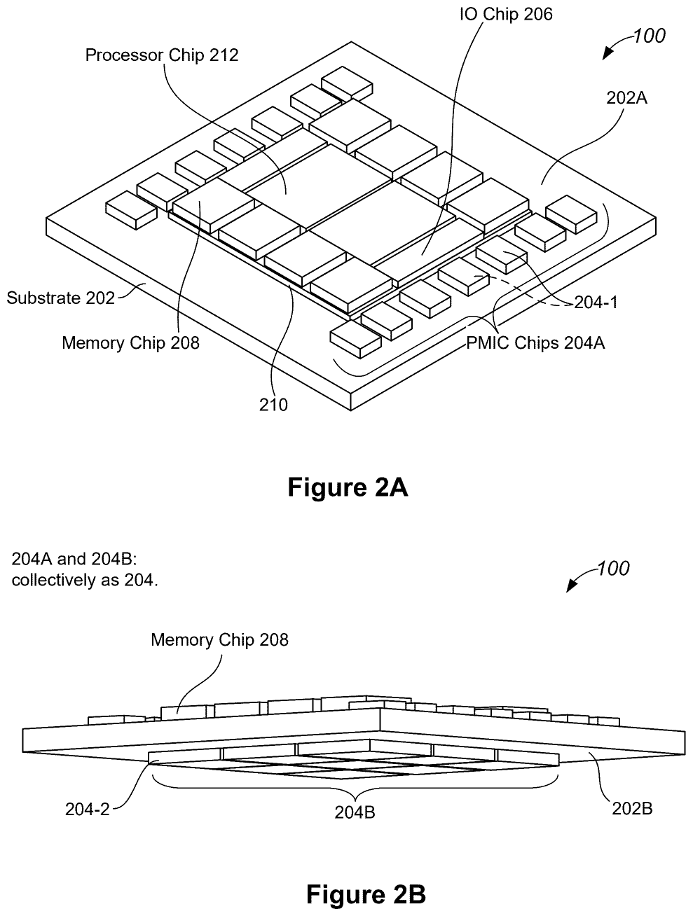

In some implementations, the electronic system 100 corresponds to an SoC 120. Different components of the electronic system 100 may be formed on two or more integrated circuits distributed on two or more chips, which are further assembled on a single substrate (e.g., substrate 202 in FIG. 2A) of the SoC 120. Alternatively, in some implementations, different components of the electronic system 100 are included in an integrated circuit formed on a single substrate of the SoC 120. In an example, the SoC 120 includes one of a silicon substrate, a polymeric substrate, a glass substrate, or a printed circuit board (PCB). Examples of the polymeric substrate include, but are not limited to, polyimide (PI), polyethylene terephthalate (PET), and polydimethylsiloxane (PDMS).

In some implementations, the SoC 120 further includes an SoC control agent 118 that refers to a control mechanism or module within the SoC 120. The SoC control agent 118 is configured to manage operation of different components (e.g., components 102-110) integrated on the SoC 120. More specifically, in some implementations, the SoC control agent 118 is configured to perform one or more of: resource management, inter-component communication, power management, task scheduling, security management, thermal management. For example, the SoC control agent 118 may: allocate resources like power, processing time, and memory bandwidth to different components of the SoC 120; manage communication between various components, such as coordinating data transfers between the processor module 102 and peripherals; turn off or put certain components into a low-power state when they are not in use to conserve energy; manage scheduling of different tasks or operations across processing units of the processor module 102 within the SoC 120; implement security features (e.g., using hardware security modules, encryption, and access control); and/or monitor temperature sensors and adjust operation (e.g., reduce clock speeds) to prevent overheating. In an example, the SoC control agent 118 includes one or more of: a power controller, a bus controller, and a clock controller. In some implementations, the SoC control agent 118 is implemented on a firmware level, e.g., by adjusting system parameters dynamically based on workloads or external conditions.

In some implementations, the processor module 102 includes one or more processing units. In some implementations, the processor module 102 includes two or more different types of processing units including a subset of: one or more central processing units (CPUs) 102C, one or more graphics processing units (GPU) 102G, a digital signal processor (DSP), a neural processing unit (NPU) (also called artificial intelligence (AI) accelerator), an image signal processors (ISP), a video processing unit (VPU), an audio processing unit (APU), a secure microcontroller, and a field programmable gate array (FPGA). The CPUs 102C are configured to execute instructions from software (e.g., operating systems, applications). Examples of CPU architecture include, but are not limited to, reduced instruction set computing (RISC) and complex instruction set computing (CIS). The GPUs 102G are configured to render graphics and handle tasks that require parallel processing, such as image processing, video encoding/decoding, and machine learning.

In some implementations, one or more of the network interfaces 108 are configured to enable communication between the SoC 120 and external networks, such as local area networks (LANs) or the Internet, and can include both hardware and software components that handle data transmission, reception, and protocol management. For instance, the network interfaces 108 may include one or more interfaces for Wi-Fi, Ethernet, and Bluetooth networks, each allowing the electronic system 100 to exchange data with an external source, and participate in networked applications, such as Internet of Things (IoT), mobile communications, or cloud computing.

In some implementations, the memory modules 104 include high-speed random-access memory, such as static random-access memory (SRAM), double data rate (DDR) dynamic random-access memory (DRAM), or other random-access solid state memory devices. In some implementations, the memory modules 104 include non-volatile memory, such as one or more magnetic disk storage devices, optical disk storage devices, flash memory devices, or other non-volatile solid state storage devices. In some implementations, the memory modules 104, or alternatively the non-volatile memory device(s) within the memory modules 104, include a non-transitory computer readable storage medium. In an example, a memory module 104 includes a high bandwidth memory (HBM) configured to provide a data bandwidth greater than a bandwidth threshold to support GPUs 102G. The HBM can include a plurality of memory dies that are stacked vertically on top of each other. In some implementations, the electronic system 100 further includes a memory controller 122 coupled to manage memory access requests for the memory modules 104.

As described further herein, in some examples, one PMIC module 112 can distribute a common shared reference signal to one or more other PMIC modules 112. The common shared reference signal can be provided to a portion, or all, of the Voltage Regulation Units (VRUs) of the other PMIC modules 112. Moreover, in some implementations, any of the PMIC modules 112 can be configured as a reference signal master, or a reference signal slave. When configured as a reference signal master, a PMIC module 112 generates and outputs via a reference signal pin the common shared reference signal. When configured as a reference signal slave, a PMIC module 112 receives the common shared reference signal via a reference signal pin (e.g., from the PMIC module 112 configured as a reference signal master).

FIGS. 2A and 2B are a top perspective view and a bottom perspective view of an example electronic system 100, in accordance with some implementations, respectively. The electronic system 100 includes an SoC 120 having a substrate 202. The substrate 202 includes a first surface 202A and a second surface 202B that is opposite to the first surface 202A. The substrate 202 may be one of a silicon substrate, a polymeric substrate, a glass substrate, or a PCB. Examples of the polymeric substrate include, but are not limited to, PI, PET, and PDMS. In some implementations, each electronic component of the electronic system 100 corresponds to a region of the substrate 202, and includes a portion of an integrated circuit of the SoC 120. Alternatively, in some implementations, each electronic component of the electronic system 100 includes one or more chips that are mounted onto the substrate 202, e.g., with or without an intermediate support structure 210. In an example, the substrate 202 is made of a polymeric material, and the intermediate support structure 210 is made of silicon and applied to mechanically support a plurality of components (e.g., including an IO chip 206, a memory chip 208, a processor chip 212).

In some implementations not shown, all electronic components included in the electronic system 100 are disposed on the first surface 202A of the substrate 202. Alternatively, in some implementations, a first subset of electronic components of the electronic system 100 are disposed on the first substrate 202A of the substrate 202, and a second subset of electronic components of the electronic system 100 are disposed on the second substrate 202B of the substrate 202. In an example, one or more chips corresponding to a subset of the electronic components 102-108, 118, and 122 are disposed on the second surface 202B. In another example, one or more chips corresponding to the PMIC module 112 are disposed on the second surface 202B.

In some implementations, the PMIC module 112 includes a plurality of distinct PMIC chips 204, which further include a first set of PMIC chips 204A and a second set of PMIC chips 204B. The first set of PMIC chips 204A are disposed on the first surface 202A of the substrate 202, e.g., jointly with all or a subset of remainder components of the SoC 120 distinct form the PMIC module 112. The second set of PMIC chips 204B are disposed on the second surface 202B of the substrate 202. A rail voltage outputted by the first set of PMIC chips 204A is routed on or under the first surface 202A, e.g., by way of a configurable power plane, to access a power rail 116 of the remainder components of the SoC 120. In some implementations, a rail voltage is outputted by the second set of PMIC chips 204B and routed vertically across the substrate 202, from the second surface 202B to the first surface 202A, to access an associated power rail 116 located on or under the first surface 202A, e.g., by way of a configurable power plane.

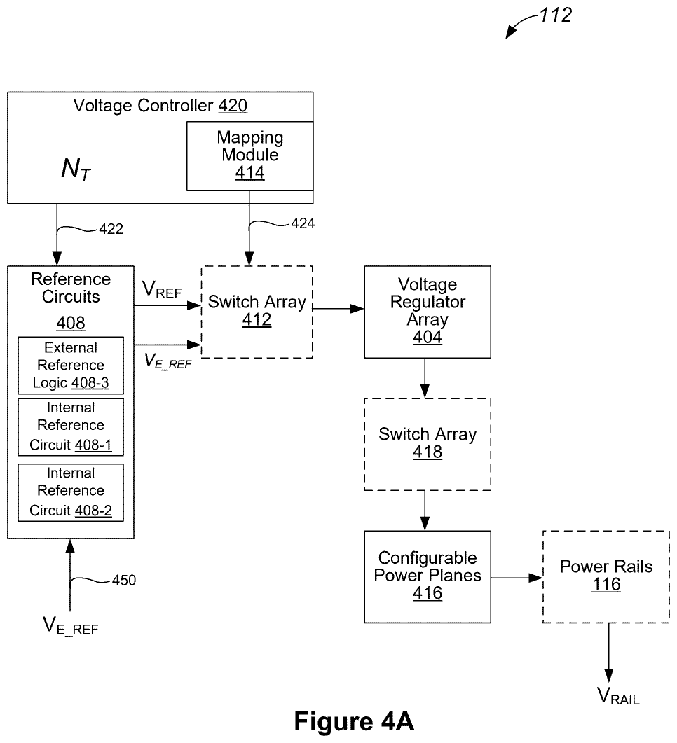

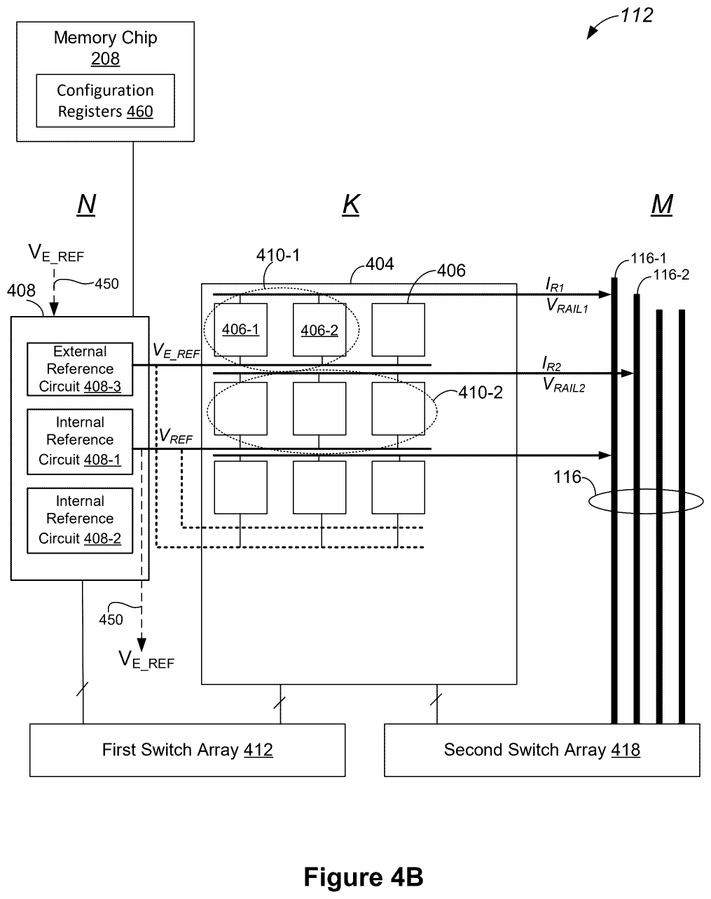

In some implementations, the PMIC module 112 includes a plurality of voltage regulation units (e.g., voltage regulation units 406 in FIG. 4B, also referred to as voltage regulation cells). In an example, a first PMIC chip 204-1 includes a subset of one or more respective voltage regulation units (e.g., voltage regulation unit 406 in FIG. 4B), and is disposed immediately adjacent to an IO chip 206 including the I/O interface 106, allowing the I/O interface 106 to access a rail voltage provided by the subset of voltage regulation units of the first PMIC chip 204-1. Alternatively, in some situations, two or more first PMIC chip 204-1 are disposed immediately adjacent to the IO chip 206 to provide the rail voltage to the IO chip 206 jointly. In another example, a memory chip 208 including one of the memory modules 104 is disposed on a location of the first surface 202A, and a second PMIC chip 204-2 is disposed a location of the second surface 202B aligned with (e.g., opposite to) the location of the first surface 202A. The second PMIC chip 204-2 includes a subset of one or more respective voltage regulation units (e.g., voltage regulation unit 406 in FIG. 4B), and allows the one of the memory modules 104 to access a rail voltage provided by the respective voltage regulation units vertically. By these means, a component of the SoC 120 may access its associated voltage regulation unit(s) located on a respective PMIC chip 204 that is disposed in proximity to the component without introducing an extended length to access a power rail 116, which helps reduce resistive and capacitive parasitics of the power rail 116 and enhance performance of the SoC 120.

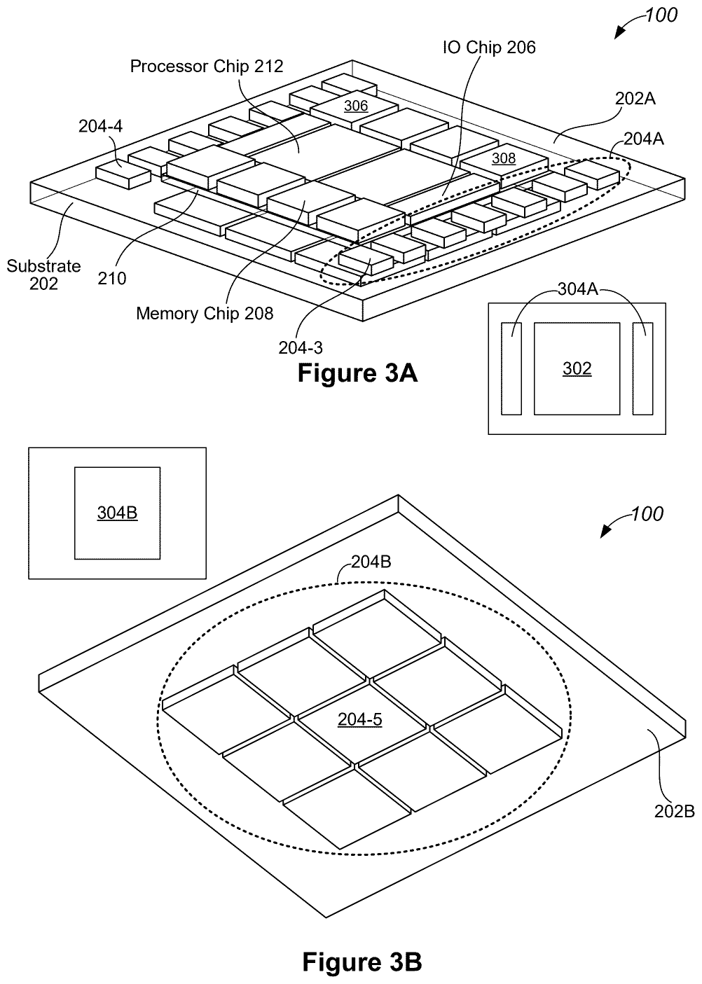

FIGS. 3A and 3B are a top perspective view and a bottom perspective view of another example electronic system 100, in accordance with some implementations, respectively. In some implementations, the first surface 202A of the substrate 202 includes a device region 302 on which a plurality of component chips (e.g., processor chip 212, IO chip 206, memory chips 208) are disposed. One or more first PMIC regions 304A (e.g., two PMIC regions) are located adjacent to the device region 302, and a first set of PMIC chips 204A are disposed on the one or more PMIC regions 304A of the first surface 202A of the substrate 202. For example, two rows of PMIC chips 204A are disposed adjacent to two opposing sides of the device region 302. In another example not shown, four rows of PMIC chips 204A are disposed adjacent to four distinct sides of the device region 302, respectively.

In some implementations not shown, the second surface 202B of the substrate 202 includes an alternative device region on which one or more component chips (e.g., processor chip 212, IO chip 206, memory chips 208) are disposed and one or more PMIC regions on which a second set of PMIC chips 204B are disposed, independently of a chip arrangement of the first surface 202A. Alternatively, in some implementations (FIG. 3B), the second surface 202B of the substrate 202 includes a second PMIC region 304B. Referring to FIG. 3A, the perspective view of the integrated electronic system 100 is depicted from the top angle with a see-through effect (e.g., to see through the substrate 202). In some implementations, the second PMIC region 304B at least partially overlaps the device region 302, allowing a component chip mounted on the device region 302 to access an output of the second PMIC region 304B using a via (e.g., a through silicon via (TSV)).

In some implementations, centers of the second PMIC region 304A and the device region 302 are aligned with one another, i.e., a center of the second PMIC region 304A and a center of the device region 302 are directly opposite to one another on two opposing surfaces 202A and 202B of the substrate 202. Further, in some implementations, sizes of the second PMIC region 304A and the device region 302 are equal to each other. Alternatively, in some implementations, the sizes of the second PMIC region 304A and the device region 302 are different from each other. Alternatively, in some implementations, the second PMIC region 304A and the device region 302 are independent from one another in size and/or in position.

In other words, the PMIC module 112 includes a plurality of voltage regulation units distributed in a subset of the plurality of PMIC chips 204. Each PMIC chip 204 is located at a respective position on the first surface 202A or the second surface 202B of the substrate 202. In some implementations, the plurality of voltage regulation units are grouped based on their locations to provide a plurality of rail voltages to a plurality of power rails 116 coupled to different components of the SoC 120. More specifically, in some implementations, each power rail 116 coupled to a component (e.g., CPU chip, GPU chip, memory chip, IO chip) is coupled to a set of voltage regulation units, which are selected based on their locations with respect to a location of the component. For example, the set of voltage regulation units are the closest to the respective component in distance compared with a remainder of the voltage regulation units, thereby controlling associated resistive and capacitive parasitics. In another example, the set of voltage regulation units, which coupled to the respective component, provides the lowest parasitic level. Among two voltage regulation units having equal distances form the respective component, a voltage regulation unit located on the first surface 202A is selected over a voltage regulation unit located on the second surface 202B. In some implementations, a voltage regulation unit located on the first surface 202A and having a larger distance from the respective component is selected over a voltage regulation unit located on the second surface 202B and having a smaller distance from the respective component.

In some implementations, the PMIC module 112 further includes a plurality of reference circuits 408 (see, e.g., FIGS. 4A and 4B). The plurality of reference circuits 408 may be formed on the same PMIC chip 204 or distributed on two or more PMIC chips 204. For example, each PMIC region 304A or 304B includes at least one PMIC chip 204 (e.g., chips 204-3, 204-4, and 204-5) dedicated to providing one or more reference circuits. In another example, all of the plurality of reference circuits used within the voltage regulation units of the PMIC module 112 are consolidated on a single PMIC chip (e.g., chip 204-5).

Alternatively, in some implementations, the plurality of reference circuits used with the voltage regulation units of the PMIC module 112 are provided by a single chip 306 or distributed among a plurality of chips (e.g., chips 306 and 308), which are mounted on, or integrated in, the device region 302.

FIG. 4A is a high-level block diagram of an example PMIC module 112, in accordance with some implementations, and FIG. 4B is a detailed block diagram of an example PMIC module 112, in accordance with some implementations. The PMIC module 112 includes, or is coupled to, a plurality of power rails 116 configured to provide one or more rail voltages V_{RAIL}. The PMIC module 112 further includes an array 404 of voltage regulation units 406 and a plurality of reference circuits 408. As described further herein, each of the plurality of reference circuits 408 are configured to generate a voltage reference V_{REF} and provide the voltage reference V_{REF} to one or more of a plurality of voltage regulator sets 410. In addition, one or more of the plurality of reference circuits 408 can be configured to receive an external reference voltage V_{E_REF} 450 from, for example, a voltage regulator chip, and can provide the external reference voltage V_{E_REF} 450 to one or more of the plurality of voltage regulator sets 410. Additionally or alternatively, one or more of the plurality of reference circuits 408 can be configured to provide the external reference voltage V_{E_REF} 450 as a reference voltage to other voltage regulator chips.

In some examples, the plurality of reference circuits 408 are coupled to, but distinct from, the array 404 of voltage regulation units 406. The array 404 of voltage regulation units 406 is coupled to the plurality of power rails 116, and configured to provide a plurality of voltage regulator sets 410. Each voltage regulator set 410 is configured to output a respective rail voltage V_{RAIL} to a respective power rail 116. In some examples, one or more of the plurality of reference circuits 408 is configured to provide a respective reference voltage V_{REF} to one or more respective voltage regulation units 406 of a respective voltage regulator set 410. The respective voltage regulator set 410 is configured to generate the respective rail voltage V_{RAIL} based on the respective reference voltage V_{REF}. In some examples, one or more of the plurality of reference circuits 408 (e.g., reference circuit 408-1) are configured to receive an external reference voltage V_{E_REF} 450 from, for example, a voltage regulator chip, and provide the external reference voltage V_{E_REF} 450 to one or more respective voltage regulation units 406 of a respective voltage regulator set 410 (e.g., voltage regulator set 406-1). The respective voltage regulator set 410 is configured to generate the respective rail voltage V_{RAIL} based on the reference voltage V_{E_REF}.

Some implementations of this application include a PMIC module 112 that has an array 404 of voltage regulation units 406, a plurality of voltage references 408 that can be selectable and programmable, and distribution circuits and buses that can be selectable. Different numbers of voltage regulation units 406 may be grouped together to form a voltage regulator set 410 for outputting a rail voltage V_{RAIL} (also called a power supply voltage). The array 404 of voltage regulation units 406 may be grouped to form a single voltage regulator set 410 or a plurality of power regulator sets 410, thereby providing a single rail voltage V_{RAIL} or multiple rail voltages V_{RAIL}. In some implementations, the PMIC module 112 provides a plurality of rail voltages V_{RAIL} correspond to a plurality of distinct voltage regulator sets 410, and each voltage regulator set 410 includes a respective number of voltage regulation units 406, independently of other voltage regulator set(s) 410. For each voltage regulator set 410, outputs of the respective voltage regulation units 406 are electrically coupled (e.g., shortened) to one another and further to a respective power rail 116. In some implementations, a voltage regulator set 410 is configured to output a variable rail voltage V_{RAIL}, e.g., to track a respective reference voltage V_{REF}, V_{E_REF}.

In some implementations, the PMIC module 112 includes, or is coupled to, a single substrate (e.g., substrate 202 in FIGS. 2A and 2B). The array 404 of voltage regulation units 406 and the plurality of reference circuits 408 are disposed on the substrate 202, separately from one another. In some implementations, the array 404 of voltage regulation units 406 and the plurality of reference circuits 408 correspond to different sets of PMIC chips 204 disposed on PMIC regions 304A and 304B (FIGS. 3A and 3B) of the substrate 202. Alternatively, in some implementations, the array 404 of voltage regulation units 406 is distributed in PMIC chips 204 disposed on the PMIC regions 304A and 304B of the substrate 202, and and the plurality of reference circuits 408 correspond to chips (e.g., chip 306 or 308 in FIG. 3A) disposed on a device region 302 (FIG. 3A) of the substrate 202.

Referring to FIG. 4B, in some implementations, the plurality of power rails 116 include a first number M of power rails 116, and the plurality of reference circuits 408 include a second number N of reference circuits 408. The second number Nis equal to or less than the first number M. Further, in some implementations, each reference circuit 408 and a respective power rail 116 is uniquely associated with each other, and the respective reference circuit 408 is configured to provide the respective reference voltage V_{REF}, V_{E_REF} to the respective voltage regulation unit set 410 assigned to generate the rail voltage V_{RAIL} for the power rail 116. A number of voltage regulation units 406 in the respective voltage regulation unit set 410 may be varied.

In some implementations, rail voltages V_{RAIL} of two power rails 116-1 and 116-2 are equal to each other, and each power rail 116 maintains a consistent voltage. In these implementations, voltage regulation units 406 contributing to each respective power rail 116-1 or 116-2 can be driven by the same respective reference circuit 408. Further, in some implementations, two voltage regulator sets 410-1 and 410-2 corresponding to the two power rails 116-1 and 116-2 are coupled to two distinct reference circuits 408-1 and 408-2. Alternatively, in some implementations, the two voltage regulator sets 410-1 and 410-2 corresponding to the two power rails 116-1 and 116-2 are coupled to the same reference circuit 408 (e.g., reference circuit 408-1). In some examples, one or more of the reference circuits 408 can provide the reference voltage V_{E_REF} to any number of the voltage regulator sets 410 corresponding to any number of the power rails 116. As such, the second number N of the reference circuits 408 can be equal to or less than the first number M of the power rails 116.

In some implementations, the plurality of power rails 116 include a first number M of power rails 116, and the plurality of reference circuits 408 include a second number N of reference circuits 408. The array 404 of voltage regulation units 406 includes a third number K of voltage regulation units 406. The second number N can be equal to or less than (≤) the third number K, and the first number M can be equal to or less than (≤) the third number K.

In some implementations, the PMIC module 112 includes a first switch array 412 (e.g., having the second number N of rows and the third number K of columns, or the second number N of columns and the third number K of rows). For example, rows of the first switch array 412 are electrically coupled to the second number N of reference circuits 408, and columns of the first switch array 412 are electrically coupled to the third number K of voltage regulation units 406 of the array 404. Each row-column cross section of the first switch array 412 includes a switch component configured to control coupling of a respective reference circuit 408 and a respective voltage regulation unit 406. For each voltage regulator set 410 (e.g., set 410-1 in FIG. 4B), a respective set of switch components of the first switch array 412 are enabled to couple the respective reference circuit 408 (e.g., reference circuit 408-1) to the one or more respective voltage regulation units 406 (e.g., voltage regulation units 406-1 and 406-2). Note that, in some implementations, lines connecting the reference circuits 408-1, 408-2 directly to the voltage regulation units 406 in the voltage regulator sets 410-1 and 410-2 may not correspond to interconnects and are drawn in FIG. 4B merely for illustrative purposes.

Referring back to FIG. 4A, in some implementations, the PMIC module 112 further includes a mapping module 414 coupled to the first switch array 412. The mapping module 414 is configured to control the switch components of the first switch array 412 to group the voltage regulation units 406 to form the plurality of voltage regulator sets 410. More specifically, the mapping module 414 is configured to determine whether to enable or disable each of the switch components of the first switch array 412.

In some implementations, the PMIC module 112 further includes a plurality of configurable power planes 416 embedded in a module substrate of the PMIC module 112 or a substrate 202 to which the PMIC module 112 is mounted. Each of the plurality of power rails 116 is electrically coupled to a respective power plane 416, and extends to one or more electrical components (e.g., modules 102-108) to provide a respective rail voltage V_{RAIL} to these components. Each output of voltage regulation units 406 of a respective voltage regulator set 410 is also electrically coupled to the respective power plane 416, providing the power voltage V_{RAIL} to the respective power plane 416.

Further, referring to FIG. 4B, in some implementations, the PMIC module 112 includes a second switch array 418 (e.g., having the first number M of rows and the third number K of columns, or the first number M of columns and the third number K of rows). For example, rows of the first switch array 412 are electrically coupled to the first number M of power rails 116 or configurable power planes 416, and columns of the second switch array 418 are electrically coupled to outputs of the third number K of voltage regulation units 406 of the array 404. Each row-column cross section of the second switch array 418 includes a switch component configured to control coupling a respective voltage regulation unit 406 to a respective configurable power plane 416 or to a respective power rail 116. For each voltage regulator set 410 (e.g., set 410-1 in FIG. 4B), a respective set of switch components of the first switch array 412 are enabled to couple the one or more respective voltage regulation units 406 (e.g., voltage regulation units 406-1 and 406-2) to a respective configurable power plane 416 or to the respective power rail 116 (e.g., rail 116-1). Additionally, in some implementations, the second switch array 418 and the first switch array 412 are integrated in a single switch array.

Note that, in some implementations, lines connecting the power rails 116-1 and 116-2 directly to the voltage regulation units 406 in the voltage regulator sets 410-1 and 410-2 may not correspond to interconnects and are drawn in FIG. 4B merely for illustrative purposes.

In some implementations, the plurality of voltage regulator sets 410 include a first voltage regulator set 410-1 that is configured to output a first rail voltage V_{RAIL1} (e.g., 1.2V, 0.8V) to a first power rail 116-1, and the first rail voltage is equal to a first reference voltage V_{REF} provided by a first reference circuit 408-1. In some implementations, the first rail voltage is equal to the reference voltage V_{E_REF} provided by the first reference circuit 408-1. Stated another way, an output voltage level of each voltage regulator set 410 is set by its associated reference voltage, and the voltage regulator set 410 is configured to track its associated reference voltage provided by a respective reference circuit 408.

Referring back to FIG. 4A, in some implementations, the PMIC module 112 further includes a voltage controller 420 coupled to the plurality of reference circuits 408. The voltage controller 420 is configured to generate a digital control signal 422 based on the first rail voltage associated with the first power rail 116-1 and provide the digital control signal 422 to the first reference circuit 408-1 defining the first reference voltage V_{REF}. The first power rail 116-1 extends to one or more electrical components (e.g., modules 102-108) to provide the first rail voltage to these components. Characteristics of the first power rail 116-1 (e.g., rail current, rail voltage) are determined based on operation of the one or more electrical components. The first reference voltage of the first reference circuit 408-1 is further determined and set based on the characteristics of the first power rail 116-1. In some implementations, the plurality of internal reference circuits 408-1, 408-2 are identical to one another. The digital control signal 422 determines magnitudes of the reference voltages V_{REF} outputted by the internal reference circuits 408-1, 408-2. Conversely, in some implementations, at least two of the plurality of internal reference circuits 408-1, 408-2 are different from one another. In an example, each internal reference circuit 408-1, 408-2 includes a digital-to-analog converter (DAC).

Additionally, in some implementations, the first voltage regulator set 410-1 further includes a target number N_{T} (e.g., 2) of voltage regulation units 406 and is configured to deliver up to a predefined rail current I_{RAIL} to the first power rail 116-1. The target number N_{T} is determined based on the predefined rail current I_{RAIL}, e.g., equal to the predefined rail current I_{RAIL} divided by a regulator current I_{VGC} that is deliverable by each voltage regulation unit 406. Additionally, in some implementations, the PMIC module 112 further includes a voltage controller 420 coupled to the array 404 of voltage regulation units 406. The voltage controller 420 is configured to determine the target number N_{T} based on the predefined rail current I_{RAIL} associated with the first power rail 116-1, generate one or more select signals 424 based on the target number N_{T}, and provide the one or more select signals 424 to the array 404 of voltage regulation units 406 to select the target number N_{T} of voltage regulation units 406 (e.g., voltage regulation units 406-1 and 406-2) of the first voltage regulator 116-1. In some implementations, the mapping module 414 is part of the voltage controller 420.

In some implementations, voltage regulation units 406 in the array 404 of voltage regulation units 406 are identical to each other. An output voltage of each voltage regulation unit 406 is determined based on a respective reference voltage V_{REF} received by the respective voltage regulation unit 406. The higher a rail current I_{RAIL} of a power rail 116, the larger the target number N_{T} of the voltage regulation units 406 grouped to drive the power rail 116.

Conversely, in some implementations, at least two voltage regulation units 406 in the array 404 of voltage regulation units 406 are different from one another. For example, an output voltage of each voltage regulation unit 406 is determined based on a respective reference voltage V_{REF}, V_{E_REF}, received by the respective voltage regulation unit 406. The two voltage regulation units 406 may have different driving capabilities (e.g., different regulator currents). Different numbers of the two voltage regulation units 406 may be selected and combined based on a rail current I_{RAIL} associated with a power rail 116 and regulator currents I_{VGC} of the two voltage regulation units 406.

In some implementations, the electronic system 100 includes a substrate 202, and the array 404 of voltage regulation units 406 and the plurality of reference circuits 408 are disposed on the substrate, separately from one another.

In some implementations, the electronic system 100 includes a substrate, and the array 404 of voltage regulation units 406 and the plurality of reference circuits 408 are formed by semiconductor manufacturing on the top surface of the substrate. The array 404 of voltage regulation units 406 and the plurality of reference circuits 408 are formed on two different chip areas of the substrate. In other words, each voltage regulation unit 406 does not have a separate and dedicated reference circuit 408 locally within the voltage regulation unit 406.

Referring back to FIG. 4B, in some implementations, a memory chip 208 (e.g., a programmable memory) can store one or more configuration registers 460 that define a reference voltage mode of the PMIC module 112. For example, the configuration registers 460 can define whether the PMIC module 112 is in an intra-chiplet rail mode, a cross-chiplet master mode (also referred to as reference signal master mode), or a cross-chiplet slave mode (also referred to as reference signal slave mode). When in the intra-chiplet rail mode, the PMIC module 112 only uses reference voltages generated by one or more of the reference circuits 408. For example, each voltage regulator set 410 of the PMIC module 112 can only receive a target reference voltage V_{REF} generated by a reference circuit 408. When the PMIC module 112 is configured in the cross-chiplet master mode, the PMIC module 112 provides a reference voltage generated by a reference circuit 408 (e.g., reference circuit 408-1) as V_{E_REF} 450 to, for instance, other PMIC modules. In this mode, the PMIC module 112 can configure a pin (e.g., an SREF pin) as an output, and can drive the pin with the generated reference voltage V_{E_REF} 450. As such, the PMIC module 112 can share the generated reference voltage V_{E_REF} 450 with other chiplets. Further, when configured in the cross-chiplet slave mode, the PMIC module 112 can configure a pin (e.g., the SREF pin) as an input, and can receive an external reference voltage V_{E_REF} 450 via the configured pin. The PMIC module 112 can then provide the external reference voltage V_{E_REF} 450 to one or more of the voltage regulator sets 410, as described herein.

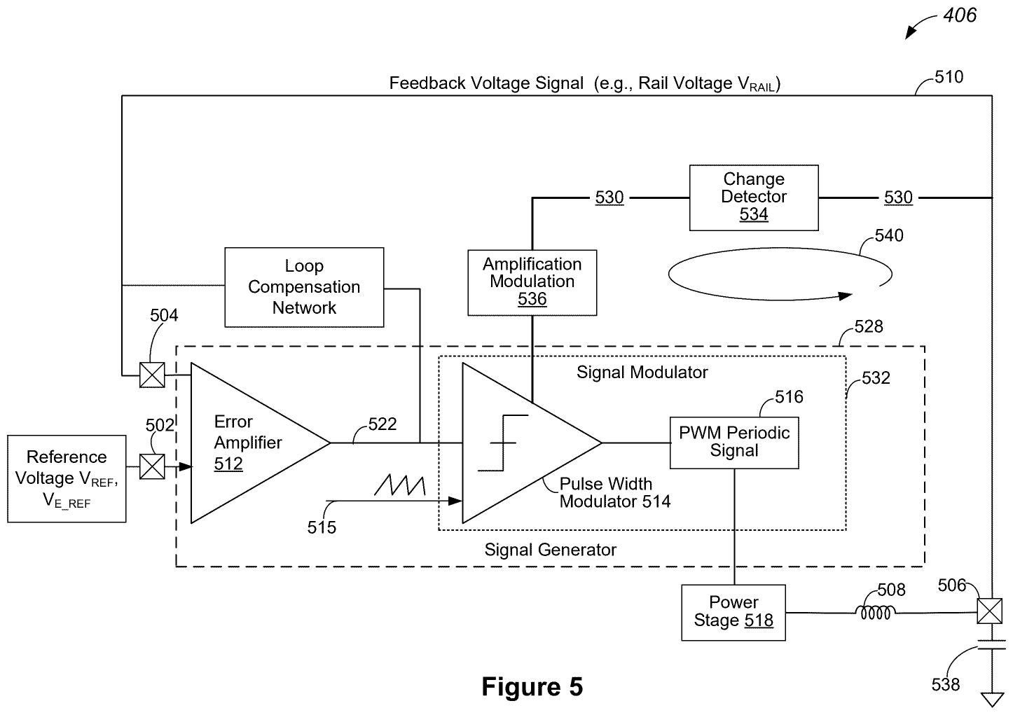

FIG. 5 is a schematic diagram of an example voltage regulation unit 406, in accordance with some implementations. In some implementations, the voltage regulation unit 406 includes an input reference interface 502 for receiving a target reference voltage V_{REF} (which, as described herein, can include external reference voltage V_{E_REF} 450), an input signal interface 504 for receiving an input signal (e.g., rail voltage V_{RAIL}), an output interface 506 for providing a rail voltage V_{RAIL} to a power rail (e.g., power rail 116-1 in FIG. 4B), a first feedback path 510 coupling the output interface 506 of the voltage regulation unit 406 to the input signal interface 504 of the voltage regulation unit 406, and an inductor 508 electrically coupled between the input signal interface 504 and the output interface 506.

In some implementations, the voltage regulation unit 406 includes an error amplifier 512, a pulse width modulator 514, a power stage 518, and the feedback path 510. The error amplifier 512 is configured to receive a reference voltage V_{REF} and a rail voltage V_{RAIL} and generate an amplified difference signal 522. The pulse width modulator 514 is coupled to the error amplifier 512 configured to generate a pulse width modulated (PWM) periodic signal 516 having a pulse width and a feature frequency f. In an example, the pulse width modulator 514 includes a comparator, and receives an input signal 515 having a Sawtooth waveform or a triangular waveform. The pulse width modulator 514 is coupled to the error amplifier 512 and configured to modulate the pulse width of the input signal 515. The power stage 518 is coupled to the pulse width modulator 514 and configured to generate the rail voltage V_{RAIL} based on the PWM periodic signal 516. In an example, the power stage 518 includes one or more power field effect transistors (FETs). The feedback path 510 is configured to couple an output of the power stage 518 to an input of the error amplifier 512, e.g., jointly with an inductor 508.

In some implementations, the voltage regulation unit 406 includes a signal generator 528, a power stage 518, and a first feedback path 510 coupling an output of the power stage to a signal input of the signal generator 528. The signal generator 528 is configured to receive a target reference voltage V_{REF} and a rail voltage V_{RAIL} and generate a PWM periodic signal 516 having a target pulse width. The power stage 518 is coupled to the signal generator 528 and configured to generate the rail voltage based on the PWM periodic signal 516 having the target pulse width. Further, in some implementations, in the voltage regulation unit 406, a second feedback path 530 couples the output of the power stage 518 to a signal modulator 532 of the signal generator 528. The second feedback path 530 is configured to pull the rail voltage V_{RAIL} back to the target reference voltage V_{REF} when the rail voltage V_{RAIL} deviates from the target reference voltage V_{REF} at a deviation rate higher than a characteristic circuit rate of the voltage regulation unit 406.

Further, in some implementations, the second feedback path 530 further includes a change detector 534 and an amplification and modulation circuit 536. The change detector 534 is coupled to the output of the power stage 518, and configured to detect the rail voltage V_{RAIL} deviating from the target reference voltage V_{REF} at the deviation rate. The amplification and modulation circuit 536 is coupled to the change detector 534 and the signal modulator 532, and configured to adjust a pulse width of the PWM periodic signal 516 in real-time, when the rail voltage V_{RAIL} deviates from the target reference voltage V_{REF} at the deviation rate. In other words, in some implementations, the change detector 534 is configured to sense fast voltage changes in the feedback voltage signal in the first feedback path 510 (e.g., corresponding to fast voltage changes in an output of the voltage regulation unit 406). The change detector 534 generates a modulation signal to modulate the signal modulator 532, thereby preventing an output of the voltage regulation unit 406 from deviating from the reference voltage V_{REF}.

State another way, in some implementations, the voltage regulation unit 406 is implemented based on a regulation control loop using one or more of a power stage 518, an integrated on-chip inductor 508, and a feedback voltage signal (e.g., carrying rail voltage V_{RAIL} in a first feedback path 510). The regulation control loop tracks a difference between voltage feedback signal and the selected reference voltage V_{REF}, and generates pulse width modulated signals (e.g., PWM periodic signal 516) driving the power stage 518. The output of the power stage 518 may drive an integrated on-chip inductor 508.

In some implementations, an inductor 508 and an output filter capacitor 538 forms an output filter. The output filter may be part of, or external to, a respective voltage regulation unit 406. The output filter may partially belong to a respective voltage regulation unit 406. The output filter capacitor 538 may be embedded in a GPU or CPU package substrate, a substrate of the SoC 120 (e.g., substrate 202), or a processor chip 212 (FIG. 2A). In some implementations, for a voltage regulator set 410, output terminals of on-chip inductors 508 of voltage regulation units 406 of the voltage regulator set 410 correspond to the output interface 506, and are coupled via interconnects to an output filter capacitor 538, which may be external to the voltage regulation units 406. Stated another way, the voltage regulation units 406 of the voltage regulator set 410 share, and is routed separately via the interconnects to, a common output filter capacitor 538. Further, in some implementations, the feedback voltage signal carried by the feedback path 510 is connected to the output filter capacitor via the interconnects extending external to the voltage regulation units 406.

Additionally, in some implementations, a regulation control mechanism of a voltage regulation unit 406 employs dual control loops including the regulation control loop and a transient modulation loop 540. The regulation control loop is based on the first feedback path 510, and configured to modulate the PWM periodic signal 516 based on an error signal (e.g., amplified difference signal 522) generated by integrating a difference between the reference voltage V_{REF} and the feedback voltage signal. In some implementations, the regulation control loop integrates a difference between the reference voltage V_{REF} and the feedback voltage signal, and includes a signal modulator 532, which is shared with the transient modulation loop 540. The amplified difference signal 522 reflects integration of the difference between the reference voltage V_{REF} and the feedback voltage signal, and is applied to modulate the PWM periodic signal 516 and generate a rail voltage V_{RAIL} to be outputted at the output interface 506 of the voltage regulation unit 406. The rail voltage V_{RAIL} settles at the associated reference voltage V_{REF}. Additionally, the transient modulation loop 540 is configured to modulate the PWM periodic signal 516 based on detection of transient characteristics of the feedback voltage signal (e.g., the rail voltage V_{REF}).

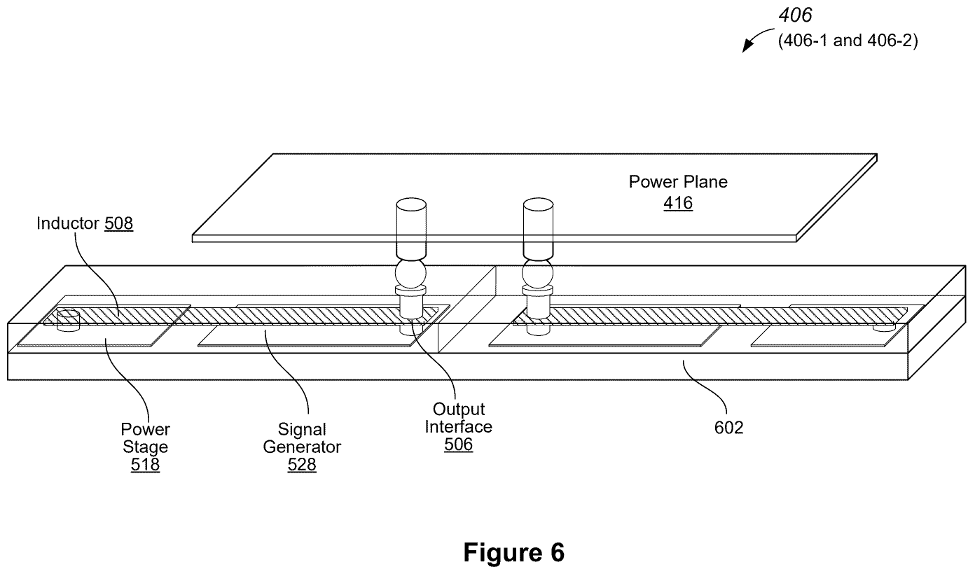

FIG. 6 illustrates two example voltage regulation units 406-1 and 406-2 (also shown in FIG. 4B) for providing a rail voltage V_{RAIL}, in accordance with some implementations. Each of the two voltage regulation units 406-1 and 406-2 includes a respective inductor 508 electrically coupled to an output interface 506 of the respective voltage regulation unit 406. In some implementations, for each voltage regulation unit 406-1 or 406-2, the respective inductor 508 is integrated on chip, e.g., monolithically formed on a respective PMIC chip 204. In some implementations, a configurable power plane 416 is embedded in a module substrate of a PMIC module 112 or a substrate 202 of the SoC 120 to which a PMIC module 112 is mounted. The two voltage regulation units 406-1 and 406-2 may be formed on a common chip substrate 602 or on two distinct chip substrates 602. The output interfaces 506 of the two voltage regulation units 406-1 and 406-2 are electrically coupled to the power plane 416, which is further coupled to a power rail 116 (not shown on FIG. 6).

In some implementations, the inductor 508 is integrated on the voltage regulation unit substrate 602, e.g., above the signal generator 528, the power stage 518, and/or any other circuits 408, 412, 418, or 420 of the PMIC module 112. An input terminal of the inductor 508 is coupled to an output of the power stage 518, e.g., using a via, a metallic layer, a solder ball, a redistribution layer (RDL), or a combination thereof. In an example, an output terminal of the inductor 508 corresponds to an output of the inductor 508, and is connected to an interconnect that couples the inductor 508 to a bump or a solder ball of the PMIC module 112. The bump or solder ball is applied to electrically couple the PMIC module 112 to other electrical components (e.g., components 102-108) of an SoC 120. In some implementations, each of two terminals of the inductor 508 includes a respective interconnect made of a via, a metallic layer, an RDL, or a combination thereof, and is configured to provide a Kelvin sensing point.

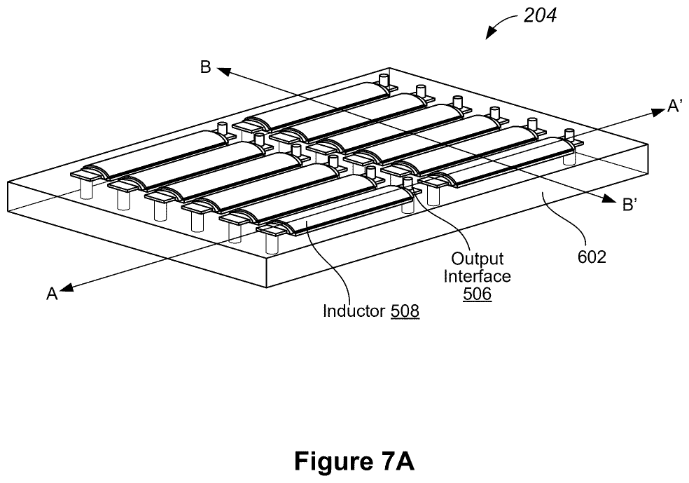

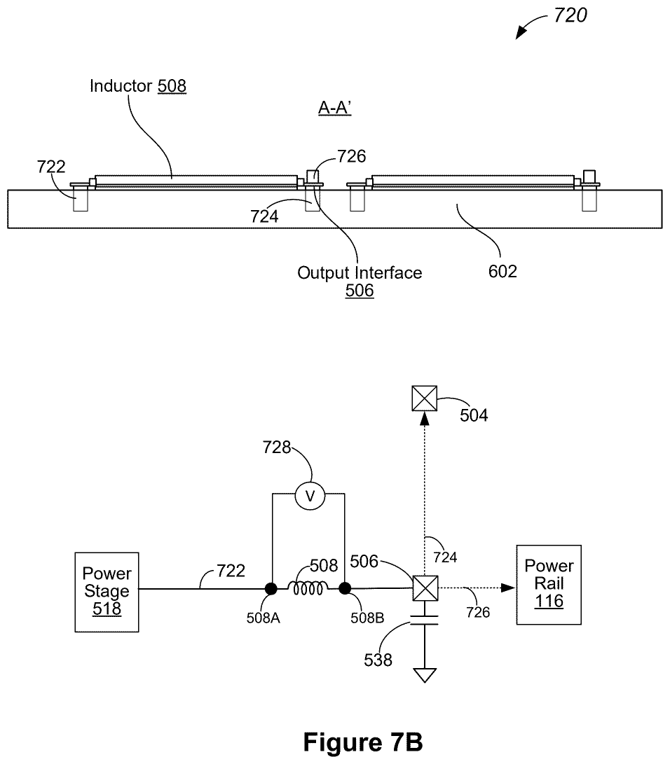

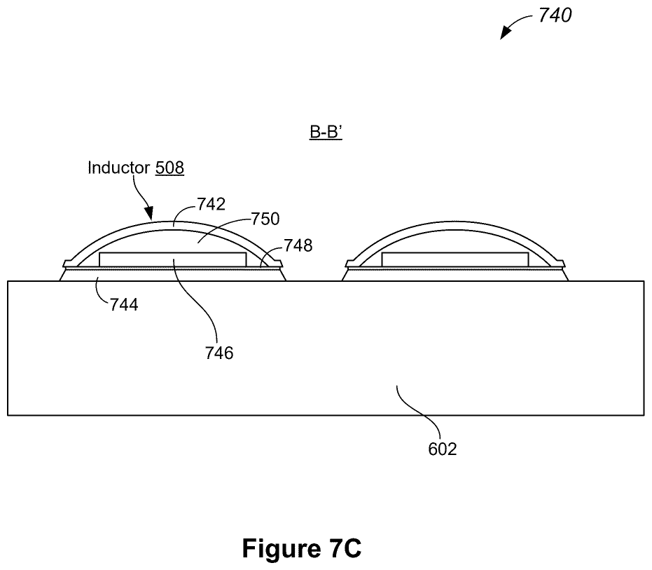

FIG. 7A is a perspective view of an example PMIC chip 204 including a plurality of inductors 508 coupled in a plurality of voltage regulation units 406, in accordance with some implementations, and FIGS. 7B and 7C are two cross sectional views 720 and 740 of a portion of the PMIC chip 204 shown in FIG. 7A including two inductors 508 of two voltage regulation units 406, in accordance with some implementations. The PMIC chip 204 has a chip substrate 602 and includes twelve voltage regulation units 406 formed monolithically on a top surface of the chip substrate 602. Each voltage regulation unit 406 includes a respective inductor 508 integrated on the top surface of the chip substrate 602. Stated another way, the voltage regulation units 406 (e.g., transistors and metal interconnects) may be formed on the voltage regulation unit substrate 602 and partially underneath the inductor 508. The PMIC chip 204 includes two cross sections AA′ and BB′ that are perpendicular to one another and to the top surface of the chip substrate 602. The cross section AA′ is shown in FIG. 7B, and part of the cross section BB′ is shown in FIG. 7C.

Referring to FIG. 7B, in some implementations, an inductor 508 includes three vias 722, 724, and 726. A first via 722 is coupled between an output a power stage 518) of a respective voltage regulation unit 406 to an input terminal 508A of the inductor 508, driving current toward the inductor 508. In some implementations, a second via 724 is coupled between an output terminal 508B of the respective inductor 508. The output terminal 508B of the respective inductor 508 corresponds to an output port 506 of the voltage regulation unit 406. Alternatively, in some implementations, the second via 724 is coupled between the output terminal 508B of the respective inductor 508 and an input signal interface 504 (FIG. 5). A third via 726 is coupled between the output terminal 508B of the inductor 508 and a power rail 116 powering other components (e.g., components 102-108 in FIG. 1) of an SoC 120, providing current and power to enable operations of the other components of the SoC 120. In some implementations, the third via 726 couples the output terminal 508B of the inductor 508 to the power rail 116 via a configurable power plane 416 (FIG. 6). In some implementations, the third via 726 is vertically aligned with the second via 724. In some implementations not shown, the third via 726 is laterally shifted (i.e., not vertically aligned) with respect to the second via 724.

In some embodiments, the first via 722 and the second via 724 enable Kelvin connections for sensing a current passing a conduction trace of the inductor 508. A current sensing circuit 728 is coupled to the input terminals 508A and the output terminal 508B of the inductor 508, and configured to measure a voltage drop on the inductor 508. Given that a resistance of the inductor 508 is known, the voltage drop is applied to determine a current passing through the inductor 508.

In some implementations, each of two terminals 508A and 508B of the inductor 508 includes a respective interconnect made of a via, a metallic layer, an RDL, or a combination thereof. The respective interconnect forms a Kelvin connection, which may be coupled to a current sensing circuit associated with the voltage regulation unit 406 for sensing an inductor current running through the inductor 508. In some implementations, a distance between Kelvin connections of each voltage regulation unit 406 is substantially uniform in the array 404 of voltage regulation units 406 (e.g., in FIG. 7A). For each voltage regulator set 410, current balancing among different voltage regulation units 406 is enabled using a single shared reference circuit 408.

Referring to FIG. 7C, in some implementations, the inductor 508 is formed on top of the voltage regulation unit substrate 602 (e.g. a silicon substrate), and include at least two laminated magnetic thin film layers 742 and 744 wrapping around a conductor 746. The inductor 508 further includes an insulation film layer 748 and a dielectric filling structure 750. The two laminated magnetic thin film layers 742 and 744 are electrically isolated from the conductor 746 by the insulation film layer 748 and a dielectric filling structure 750. In some implementations, there is no gap in an enclosure formed by the two laminated magnetic thin film layers 742 and 744. Conversely, in some implementations, there is a gap in the enclosure formed by the two laminated magnetic thin film layers 742 and 744. Further, in some implementations, each of the two laminated magnetic thin film layers 742 and 744 includes a stack of alternating magnetic thin films and dielectric thin films.

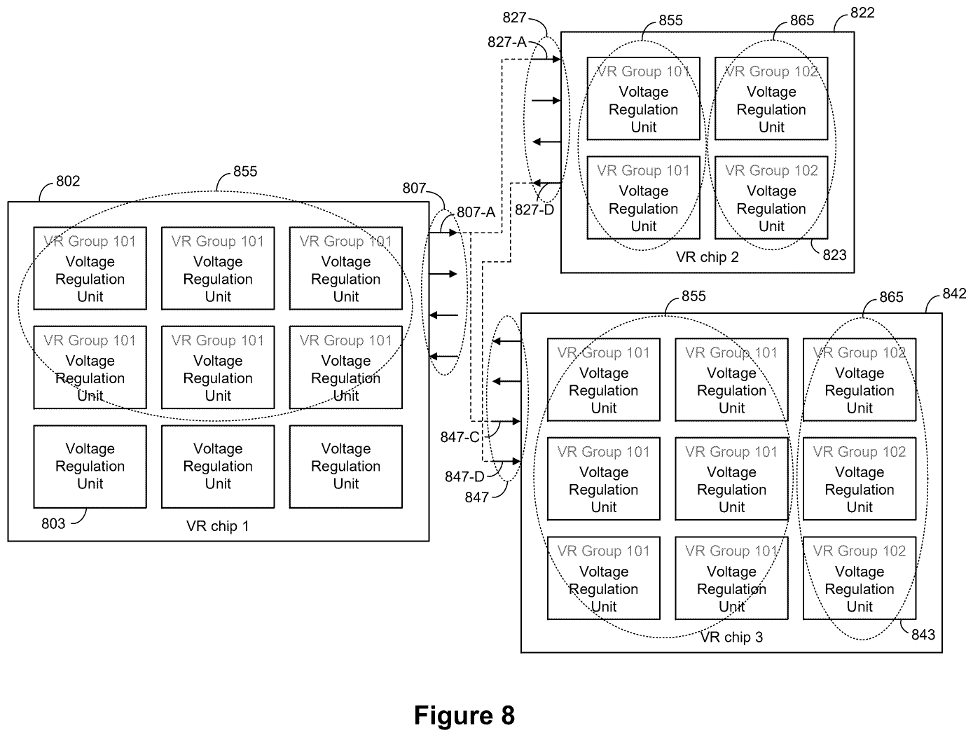

FIG. 8 illustrates a block diagram of an electronic system 800 that includes voltage regulation chiplets 802, 822, 842 configured to share reference voltages. In this example, a first voltage regulation chiplet 802 includes a plurality of voltage regulation units 803 (also referred to as voltage regulation cells). The first voltage regulation chiplet 802 also includes a plurality of pins 807. One or more of the pins 807 can be configured as an input, or an output (e.g., based on configuration registers 460). Similarly, second voltage regulation chiplet 822 includes a plurality of voltage regulation units 823, and a plurality of pins 827. In addition, third voltage regulation chiplet 842 includes a plurality of voltage regulation units 843, and a plurality of pins 847.

Further, as illustrated, a first grouping 855 of voltage regulation units includes six voltage regulation units 803 of the first voltage regulation chiplet 802, two voltage regulation units 823 of the second voltage regulation chiplet 822, and six voltage regulation units 843 of the third voltage regulation chiplet 842. The first grouping 855 defines voltage regulation units that are providing a rail voltage (e.g., V_{RAIL1}) to a same power rail (e.g., power rail 116-1), and are generating the rail voltage based on a same reference voltage (e.g., reference voltage V_{E_REF} 450).

In this example, the six voltage regulation units 803 of the first voltage regulation chiplet 802 that are part of the first grouping 855 are configured in a cross-chip master mode to provide the reference voltage on pin 807-A. As described herein, when in the cross-chip master mode, the first voltage regulation chiplet 802 can provide a reference voltage generated by an internal reference circuit (e.g., internal reference circuit 408-1) externally as a reference voltage (e.g., the reference voltage V_{E_REF} 450). As illustrated, the pin 807-A is electrically coupled to pin 827-A of the second voltage regulation chiplet 822 and to pin 847-C of the third voltage regulation chiplet 842. The two voltage regulation units 823 of the second voltage regulation chiplet 822 that are part of the first grouping 855 are configured in a cross-chip slave mode to receive the reference voltage on the pin 827-A. As described herein, when in the cross-chip slave mode, the second voltage regulation chiplet 822 can receive the external reference voltage (e.g., the reference voltage V_{E_REF} 450) via a reference circuit 408 (e.g., reference circuit 408-1), and can provide the external reference voltage to the respective voltage regulation units 823. Similarly, the six voltage regulation units 843 of the third voltage regulation chiplet 842 that are part of the first grouping 855 are also configured in a cross-chip slave mode to receive the reference voltage on the pin 847-C. As such, the voltage regulation units of the first grouping 855, which include voltage regulation units across each of the voltage regulation chiplets 802, 822, 842, can generate a rail voltage for a same rail based on a common reference voltage (i.e., the reference voltage generated by the first voltage regulation chiplet 802).

Similarly, a second grouping 865 of voltage regulation units includes two voltage regulation units 823 of the second voltage regulation chiplet 822 and three voltage regulation units 843 of the third voltage regulation chiplet 842. For the second grouping 865, the two voltage regulation units 823 of the second voltage regulation chiplet 822 are configured in a cross-chip master mode to provide a reference voltage on pin 827-D. The pin 827-D is electrically coupled to pin 847-D of the third voltage regulation chiplet 842. The three voltage regulation units 843 of the third voltage regulation chiplet 842 that are part of the second grouping 865 are configured in a cross-chip slave mode to receive the reference voltage on the pin 827-D. As such, the voltage regulation units of the second grouping 865, which include voltage regulation units across each of the second and third voltage regulation chiplets 822, 842, can generate another rail voltage for another rail based on a common reference voltage (i.e., the reference voltage generated by the second voltage regulation chiplet 822).

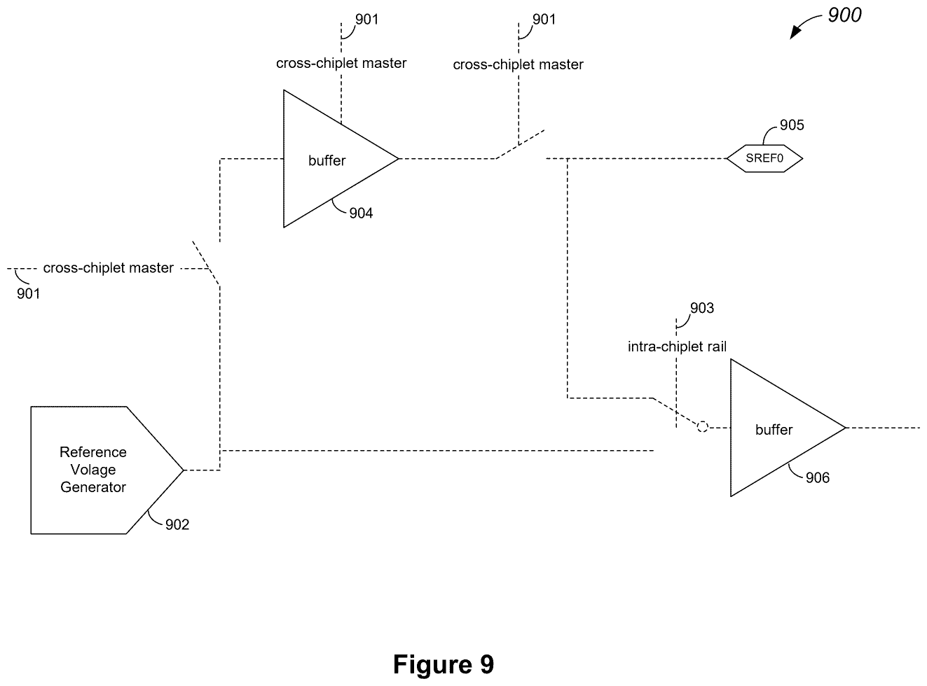

FIG. 9 illustrates an electrical circuit 900 can generate a reference voltage 905. For example, a reference circuit 408 (e.g., reference circuit 408-1) of a PMIC module 112 can include the electrical circuit 900 to generate the reference voltage V_{E_REF} 450. In this example, the electrical circuit 900 includes a reference voltage generator (e.g., digital-to-analog converter (DAC)) 902, a first buffer 904 (e.g., a voltage buffer), a second buffer 906, a first switch 910, a second switch 912, and a third switch 914. The electrical circuit 900 can receive a cross-chiplet master signal 901 and/or a cross-chiplet rail signal 903. The cross-chiplet master signal 901 indicates the cross-chiplet master mode, while the cross-chiplet rail signal 903 indicates the intra-chiplet rail mode, described herein.

The reference voltage generator 902 is configured to generate an output voltage 913. When the cross-chiplet master signal 901 is in a first state (e.g., low, high), the first switch 910 closes and allows the first buffer 904 to receive the output voltage 913. Moreover, the cross-chiplet master signal 901 enables (e.g., activates) the first buffer 904 when the cross-chiplet master signal 901 is in the first state, and causes the second switch 912 to close, thereby allowing the first buffer 904 to generate the reference voltage 905. The reference voltage 905 can be provided to a pin of the PMIC module (e.g., pin 807-A), and shared with other PMIC modules, for instance.

Moreover, the third switch 914 electrically couples the output of the second switch 912 to its input when the cross-chiplet rail signal 903 is in a first state (e.g., low, high), allowing the second buffer 906 to receive the reference voltage 905. The second buffer 906 can provide the reference voltage 905 to one or more voltage regulation units within the PMIC module 112, for instance. As such, the same reference voltage 905 can be provided to internal voltage regulation units and voltage regulation units of other chiplets.

In some implementations, the cross-chiplet master signal 901 is in a second state (e.g., different from the first state). In this example, the first switch 910 and second switch 912 open, and the first buffer is deactivated (e.g., disabled). In this example, when the cross-chiplet rail signal 903 is in a second state, the third switch 914 electrically couples an output of the reference voltage generator 902 to its input, allowing the second buffer 906 to receive the reference voltage generator's 902 output voltage 913. The output voltage 913 can be provided to one or more voltage regulation units within the PMIC module 112, for example.

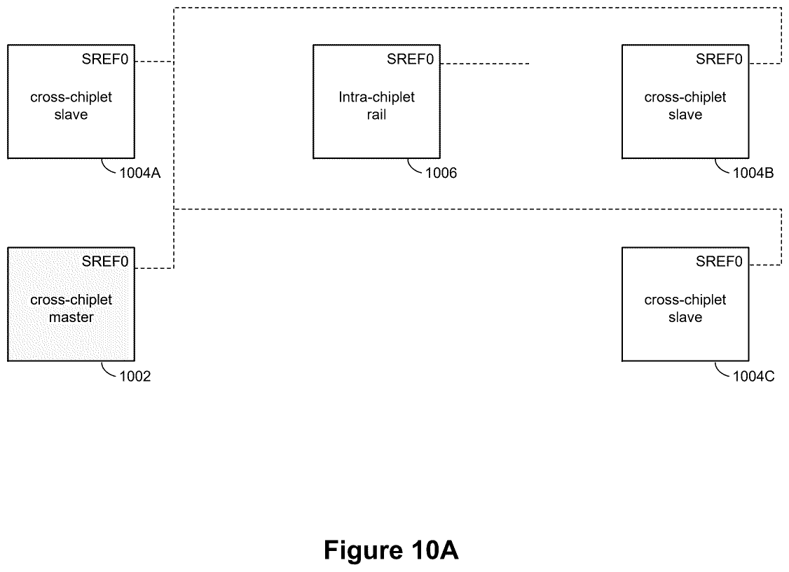

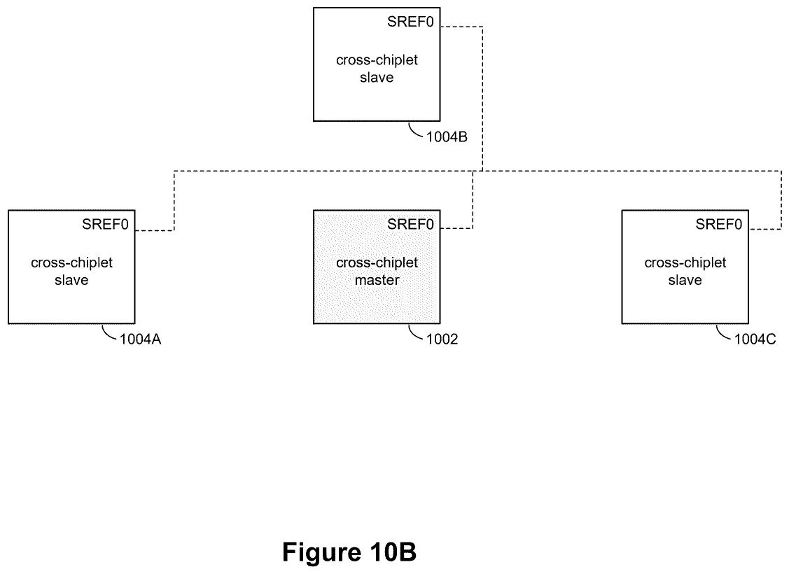

FIG. 10A illustrates chiplets in one example reference voltage configuration. In this example, a master chiplet 1002 is configured in a cross-chiplet master mode, and provides a reference voltage 1011 to a first slave chiplet 1004A, to a second slave chiplet, 1004B, and to a third slave chiplet 1004C. Each of the first slave chiplet 1004A, second slave chiplet, 1004B, and third slave chiplet 1004C are configured in a cross-chiplet slave mode. For example, the master chiplet 1003 may provide the reference voltage 1011 to its signal reference pin (SREF0) 1003. The SREF0 pin 1003 can be electrically coupled (e.g., via an interconnect) to the SREF0 pin 1005A of the first slave chiplet 1004A, as well as to the SREF0 pin 1005B of the second slave chiplet 1004B and the SREF0 pin 1005C of the third slave chiplet 1004C. Each of the first slave chiplet 1004A, second slave chiplet, 1004B, and third slave chiplet 1004C can generate a rail voltage (e.g., the same rail voltage) based on the reference voltage 1011. An intra-chiplet rail chiplet 1006, configured in an intra-chiplet rail mode, does not receive the reference voltage 1011, nor does it provide a reference voltage to any of the master chiplet 1002, the first slave chiplet 1004A, second slave chiplet, 1004B, and third slave chiplet 1004C. For example, the intra-chiplet rail chiplet 1006 may include a reference circuit that generates reference voltages for voltage regulation units within the intra-chiplet rail chiplet 1006. In this example, the master chiplet 1002 is positioned beneath the first slave chiplet 1004A and to a same side (e.g., left) of each of the second slave chiplet 1004B, the third slave chiplet 1004C, and the intra-chiplet rail chiplet 1006.

FIG. 10B illustrates chiplets in one example reference voltage configuration. In this example, the master chiplet 1002 is also configured in the cross-chiplet master mode, and provides the reference voltage 1011 to the first slave chiplet 1004A, to the second slave chiplet, 1004B, and to the third slave chiplet 1004C. Each of the first slave chiplet 1004A, second slave chiplet, 1004B, and third slave chiplet 1004C are also configured in the cross-chiplet slave mode. In this example, the master chiplet 1002 is positioned between the first slave chiplet 1004A and the third slave chiplet 1004C, and below the second slave chiplet 1004B. In addition, in this example, there are no chiplets configured in an intra-chiplet rail mode.

In some other implementations, a method is implemented to provide a rail voltage for an electronic system. The method includes grouping voltage regulation units within a first chiplet to provide a voltage regulator set. The method also includes coupling a reference circuit to the voltage regulator set, wherein the reference circuit is configured to generate a reference voltage and provide the reference voltage to the voltage regulator set and to a reference signal pin.

In some other implementations, a method is implemented to provide a rail voltage for an electronic system 100. The method includes generating a reference voltage V_{REF} by a reference circuit 408-1, and providing the reference voltage V_{REF} to a voltage regulator set 410-1 comprised of a plurality of voltage regulation units 406. Further, the method includes generating a rail voltage V_{RAIL1} by the voltage regulator set 410-1 based on the reference voltage V_{REF}, and providing the rail voltage V_{REF} 452 to a power rail 116-1. The method also includes providing the reference voltage V_{E_REF} to a reference signal pin electrically coupled to a chiplet.

In yet other implementations, a method is implemented to provide a rail voltage for an electronic system. The method includes receiving, from a chiplet, a reference voltage V_{E_REF} 450, and providing the reference voltage V_{REF} 450 to a voltage regulator set 410-1 comprised of a plurality of voltage regulation units 406. The method also includes generating, by the voltage regulator set 410-1, a rail voltage V_{RAIL1} based on the reference voltage V_{E_REF} 450, and providing the rail voltage V_{RAIL1} to a power rail 116-1.

Various examples of aspects of the disclosure are described as numbered clauses (1, 2, 3, etc.) below for convenience. These are provided as examples, and do not limit the subject technology.

Clause 1. An electronic system, comprising: a plurality of chiplets comprising at least a first chiplet and a second chiplet, wherein each of the plurality of chiplets comprise a plurality of voltage regulation units configured to provide at least a first voltage regulator set, wherein the first voltage regulator set of the first chiplet is configured to: generate a first rail voltage based on a reference voltage; provide the first rail voltage to a first power rail; and provide the reference voltage to the first voltage regulator set of the second chiplet; and wherein the first voltage regulator set of the second chiplet is configured to: generate a second rail voltage based on the reference voltage; and provide the second rail voltage to a second power rail.

Clause 2. The electronic system for clause 1, wherein: the first chiplet is configured as a master device causing the first chiplet to output the reference voltage on a voltage reference pin; and the second chiplet is configured as a slave device causing the second chiplet to receive the reference voltage from a voltage reference pin.

Clause 3. The electronic system of clause 2, wherein the first chiplet comprises a programmable memory storing configuration data that configures the first chiplet as the master device.

Clause 4: The electronic system of clause 2 or clause 3, wherein the second chiplet comprises a programmable memory storing configuration data that configures the second chiplet as the slave device.

Clause 5: The electronic system of any of clauses 1-4, wherein the plurality of chiplets comprise additional chiplets, and the first voltage regulator set of the first chiplet is configured to provide the reference voltage to the first voltage regulator set of each of the additional chiplets.

Clause 6: The electronic system of clause 5, wherein the first voltage regulator set of each of the additional chiplets are configured to generate the first rail voltage based on the reference voltage, and provide the first rail voltage to the first power rail.

Clause 7: The electronic system of any of clauses 1-6 comprising a substrate, wherein the plurality of chiplets are disposed on the substrate in a star configuration, wherein the first chiplet is disposed in a middle area of the star configuration.

Clause 8: The electronic system of any of clauses 1-7, wherein the plurality of voltage regulation units of each of the first chiplet and the second chiplet are configured to provide a second voltage regulator set, wherein the second voltage regulator set of the second chiplet is configured to provide a second reference voltage to the second regulator set of the first chiplet, and wherein the second voltage regulator set of the first chiplet is configured to generate a third rail voltage based on the second reference voltage and provide the third rail voltage to a third power rail.

Clause 9: The electronic system of any of clauses 1-8, wherein the second chiplet comprises a buffer circuit configured to: receive and buffer the reference voltage; and output the reference voltage and provide the reference voltage to a third chiplet of the plurality of chiplets.

Clause 10: The electronic system of clause 9, wherein the second chiplet comprises an input voltage reference pin and an output voltage reference pin, wherein the buffer circuit is electrically coupled to each of the input voltage reference pin and the output voltage reference pin, wherein the second chiplet receives the reference voltage on the input voltage reference pin, and the buffer circuit provides the reference voltage on the output voltage reference pin.

Clause 11: The electronic system of any of clauses 1-10, wherein the first chiplet comprises a voltage reference pin configured as an output pin, wherein the first chiplet provides the reference voltage on the voltage reference pin.

Clause 12: The electronic system of any of clauses 1-11, wherein the second chiplet comprises a voltage reference pin configured as an input pin, wherein the second chiplet receives the reference voltage on the voltage reference pin.

Clause 13: The electronic system of any of clauses 1-12, wherein the first voltage regulator set of the first chiplet comprises an analog-to-digital converter configured to generate the reference voltage.

Clause 14: The electronic system of clause 13, wherein the first voltage regulator set of the first chiplet comprises an inductor configured to receive the reference voltage from the analog-to-digital converter and provide the reference voltage to the first voltage regulator set of the second chiplet.

Clause 15: The electronic system of any of clauses 1-14, wherein the first chiplet comprises a voltage reference pin and one or more switches configured to provide a configuration signal, wherein the first chiplet is configured to provide the reference voltage to the voltage reference pin based on the configuration signal.

Clause 16: The electronic system of any of clauses 1-15 comprising a first circuit electrically coupled to the first power rail and configured to receive the first rail voltage from the first power rail.

Clause 17: The electronic system of clause 16 comprising a second circuit electrically coupled to the second power rail and configured to receive the second rail voltage from the second power rail.

Clause 18: The electronic system of any of clauses 1-17, wherein each voltage regulation unit further comprises: an error amplifier configured to receive the reference voltage and the first rail voltage and generate an amplified difference signal; a pulse width modulator coupled to the error amplifier and configured to generate a periodic signal having a pulse width and a feature frequency; a power stage coupled to the pulse width modulator and configured to generate the first rail voltage based on the periodic signal; and a feedback path coupling an output of the power stage to an input of the error amplifier.

Clause 19: An apparatus, comprising: a plurality of power rails configured to provide one or more rail voltages; and an electronic system in any of clauses 1-18.

Clause 20: An integrated circuit, comprising: a plurality of power rails configured to provide one or more rail voltages; and an electronic system in any of clauses 1-18.

Clause 21: A power management integrated circuit (PMIC), comprising an electronic system in any of clauses 1-18.

Clause 22: An apparatus, comprising: a plurality of power rails configured to provide one or more rail voltages; and a first chiplet comprising: a plurality of voltage regulation units coupled to the plurality of power rails; and a reference circuit coupled to the plurality of voltage regulation units, wherein the plurality of voltage regulation units are configured to provide a voltage regulator set, wherein the voltage regulator set is configured to output a rail voltage to a power rail of the plurality of power rails, wherein the reference circuit is configured to provide a reference voltage to the plurality of voltage regulation units, wherein the voltage regulator set is configured to generate the rail voltage based on the reference voltage, wherein the reference circuit is configured to provide the reference voltage to a second chiplet, and wherein the second chiplet is configured to output at least one of the one or more rail voltages to at least one of the plurality of power rails based on the reference voltage.

Clause 23: An electronic system, comprising: a power rail configured to provide a rail voltage; and a first chiplet comprising a plurality of voltage regulation units configured to provide a voltage regulator set, wherein the voltage regulator set is configured to output the rail voltage to the power rail, wherein the first chiplet is configured to: receive a reference voltage from a second chiplet; and provide the reference voltage to the plurality of voltage regulation units of the voltage regulator set, wherein the voltage regulator set is configured to generate the rail voltage based on the reference voltage.

Clause 24: A method, comprising: generating a reference voltage by a reference circuit, and providing the reference voltage to a voltage regulator set comprised of a plurality of voltage regulation units. Further, the method includes generating a rail voltage by the voltage regulator set based on the reference voltage, and providing the rail voltage to a power rail. The method also includes providing the reference voltage to a reference signal pin electrically coupled to a chiplet, wherein the method is implemented by an electronic system in any of clauses.

Clause 25: A method, comprising: receiving, from a chiplet, a reference voltage, and providing the reference voltage to a voltage regulator set comprised of a plurality of voltage regulation units. The method also includes generating, by the voltage regulator set, a rail voltage based on the reference voltage, and providing the rail voltage to a power rail.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific implementations. However, the illustrative discussions above are not intended to be exhaustive or to limit the claims to the precise forms disclosed. Many modifications and variations are possible in view of the above teachings. The implementations were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in one or more of hardware, firmware, and software (e.g., in any combination thereof).

What is claimed is:

1. An electronic system, comprising:
a plurality of chiplets comprising at least a first chiplet and a second chiplet, wherein each of the plurality of chiplets comprise a plurality of voltage regulation units configured to provide at least a first voltage regulator set, wherein the first voltage regulator set of the first chiplet is configured to:
generate a first rail voltage based on a reference voltage;
provide the first rail voltage to a first power rail; and
provide the reference voltage to the first voltage regulator set of the second chiplet; and wherein the first voltage regulator set of the second chiplet is configured to:
generate a second rail voltage based on the reference voltage; and
provide the second rail voltage to a second power rail.

2. The electronic system of claim 1, wherein:
the first chiplet is configured as a master device causing the first chiplet to output the reference voltage on a voltage reference pin; and
the second chiplet is configured as a slave device causing the second chiplet to receive the reference voltage from a voltage reference pin.

3. The electronic system of claim 2, wherein the first chiplet comprises a programmable memory storing configuration data that configures the first chiplet as the master device.

4. The electronic system of claim 2, wherein the second chiplet comprises a programmable memory storing configuration data that configures the second chiplet as the slave device.

5. The electronic system of claim 1, wherein the plurality of chiplets comprise additional chiplets, and the first voltage regulator set of the first chiplet is configured to provide the reference voltage to the first voltage regulator set of each of the additional chiplets.

6. The electronic system of claim 5, wherein the first voltage regulator set of each of the additional chiplets are configured to generate the first rail voltage based on the reference voltage, and provide the first rail voltage to the first power rail.

7. The electronic system of claim 1 comprising a substrate, wherein the plurality of chiplets are disposed on the substrate in a star configuration, wherein the first chiplet is disposed in a middle area of the star configuration.

8. The electronic system of claim 1, wherein the plurality of voltage regulation units of each of the first chiplet and the second chiplet are configured to provide a second voltage regulator set, wherein the second voltage regulator set of the second chiplet is configured to provide a second reference voltage to the second voltage regulator set of the first chiplet, and wherein the second voltage regulator set of the first chiplet is configured to generate a third rail voltage based on the second reference voltage and provide the third rail voltage to a third power rail.

9. The electronic system of claim 1, wherein the second chiplet comprises a buffer circuit configured to:
receive and buffer the reference voltage; and
output the reference voltage and provide the reference voltage to a third chiplet of the plurality of chiplets.

10. The electronic system of claim 9, wherein the second chiplet comprises an input voltage reference pin and an output voltage reference pin, wherein the buffer circuit is electrically coupled to each of the input voltage reference pin and the output voltage reference pin, wherein the second chiplet receives the reference voltage on the input voltage reference pin, and the buffer circuit provides the reference voltage on the output voltage reference pin.

11. The electronic system of claim 1, wherein the first chiplet comprises a voltage reference pin configured as an output pin, wherein the first chiplet provides the reference voltage on the voltage reference pin.

12. The electronic system of claim 1, wherein the second chiplet comprises a voltage reference pin configured as an input pin, wherein the second chiplet receives the reference voltage on the voltage reference pin.

13. The electronic system of claim 1, wherein the first voltage regulator set of the first chiplet comprises an analog-to-digital converter configured to generate the reference voltage.

14. The electronic system of claim 13, wherein the first voltage regulator set of the first chiplet comprises an inductor configured to receive the reference voltage from the analog-to-digital converter and provide the reference voltage to the first voltage regulator set of the second chiplet.

15. The electronic system of claim 1, wherein the first chiplet comprises a voltage reference pin and one or more switches configured to provide a configuration signal, wherein the first chiplet is configured to provide the reference voltage to the voltage reference pin based on the configuration signal.

16. The electronic system of claim 1 comprising a first circuit electrically coupled to the first power rail and configured to receive the first rail voltage from the first power rail.

17. The electronic system of claim 16 comprising a second circuit electrically coupled to the second power rail and configured to receive the second rail voltage from the second power rail.

18. The electronic system of claim 1, wherein each voltage regulation unit further comprises:
an error amplifier configured to receive the reference voltage and the first rail voltage and generate an amplified difference signal;
a pulse width modulator coupled to the error amplifier and configured to generate a periodic signal having a pulse width and a feature frequency;
a power stage coupled to the pulse width modulator and configured to generate the first rail voltage based on the periodic signal; and
a feedback path coupling an output of the power stage to an input of the error amplifier.

19. An apparatus, comprising:
a plurality of power rails configured to provide one or more rail voltages; and
a first chiplet comprising:
a plurality of voltage regulation units coupled to the plurality of power rails; and
a reference circuit coupled to the plurality of voltage regulation units, wherein the plurality of voltage regulation units are configured to provide a voltage regulator set, wherein the voltage regulator set is configured to output a rail voltage to a power rail of the plurality of power rails, wherein the reference circuit is configured to provide a reference voltage to the plurality of voltage regulation units, wherein the voltage regulator set is configured to generate the rail voltage based on the reference voltage, wherein the reference circuit is configured to provide the reference voltage to a second chiplet, wherein the second chiplet is configured to output at least one of the one or more rail voltages to at least one of the plurality of power rails based on the reference voltage.

20. An electronic system, comprising:
a power rail configured to provide a rail voltage; and
a first chiplet comprising a plurality of voltage regulation units configured to provide a voltage regulator set, wherein the voltage regulator set is configured to output the rail voltage to the power rail, wherein the first chiplet is configured to:
receive a reference voltage from a second chiplet; and
provide the reference voltage to the plurality of voltage regulation units of the voltage regulator set, wherein the voltage regulator set is configured to generate the rail voltage based on the reference voltage.
